(19) United States
(12) Patent Application Publication
(10) Pub. No.: US 2002/0103552 A1
(43) Pub. Date: Aug. 1, 2002

(54) Method and apparatus to reduce processing requirements for the playback of complex audio sequences

(76) Inventors: Mike Boucher, Dacula, GA (US); Ken Cowin, Flowery Branch, GA (US); Bart Smudde, Suwanee, GA (US); T. Steve Herrington, Lawrenceville, GA (US)

Correspondence Address: MATSUSHITA MOBILE COMMUNIATIONS, DEVELOPEMENT CORPORATION OF USA, 1225 NORTHBROOK PARKWAY, SUWANEE, GA, 30024, US

(21) Appl. No.: 09/750,618

(22) Filed: Dec. 4, 2000

(51) Int. Cl. G06F 17/00; H03G 5/00

(52) U.S. Cl. 700/94; 381/101

(57) ABSTRACT

An invention to off-load the processing requirements for the playback of audio sequences within an electronic device. A dual processing system is utilized in which a host processing unit manages a plurality of tone patterns and detects the occurrence of events that require the playback of one or more of the tone patterns. The host processing unit transfers the appropriate tone patterns to a supplemental processing unit. The supplemental processing unit performs all of the necessary conversions for transforming the tone patterns into audio sequences and playing the tone sequences. This advantageously allows the host processing unit to process time-critical events without being burdened by providing the playback of the tone patterns.

### TECHNICAL FIELD

This invention relates to the fields of audio signal processing and hand-held electronic devices and, more particularly, relates to reducing the processing requirements required to playback complex audio sequences, thereby allowing a processor-intensive hand-held device to incorporate complex audio sequences without degrading the performance of the hand-held device.

### BACKGROUND

As the competition within the market for hand-held and desk-top electronic devices continues to heat up, manufactures continue to seek out niches that can distinguish their products from those of their competitors and increase their share of the market. One such niche that manufactures have gravitated to is the feature niche—bells and whistles sell products. Today it is common place to find laptop computers that serve as compact disc stereos, personal data assistants that can browse the world wide web, wrist watches that include an infrared transmitter to assist the dedicated couch potato in surfing the endless supply of cable channels, and cellular telephones that flash, vibrate, beep, ring, and surf the world wide web for stock quotes, weather information, traffic information or the like.

Focusing on the cellular or mobile telephone industry, a feature gaining prominence in the market place is melody ringing. Rather than being startled in the movie theater by your neighbors telephone chirping to alert that a call is being received, we have now advanced to a point where users may be alerted of an incoming call with classical musical simulations such as the William Tell Overture or the Looney Tunes theme song.

As the marketing experts within an organization continue to push their engineers to the edge of the envelope by packing more and more features into products, the engineers are forced to once again, scratch their heads and make it happen. However, the engineers often face many competing challenges in attempting to implement additional features. For instance, within cellular technology, real-time events must be received and processed at a high-priority to ensure the provision of quality communications. As additional features are added to a cellular telephone, the processing power within the cellular telephone needs to be increased to maintain quality of service. Unfortunately, as the processing power increases, the drain on the battery power also increases. Adding additional battery cells to meet this increased demand for power is not an acceptable solution to this problem because, for a cellular telephone to be competitive in the market place, its size and weight must be reduced. So, the engineers are continually faced with the task of making products, smaller, lighter, faster, and most importantly of all, fancier.

A feature that is the focus of this invention is providing the playback of complex audio sequences with an electronic device. Within a cellular telephone device, these complex audio sequences may be used for alerting the user of an incoming call, playing back a voice memo stored within the cellular telephone, or notifying the user of a variety of other events such as low battery, call-waiting, system changes, reception of voice mail and/or reception of short messages.

One technique to provide such a feature is the use of a frequency generator. Under the control of a processor, a frequency generator can be instructed to tune to a particular frequency. The output of the frequency generator can then be fed into an audio speaker. Traditionally, this technique has been used to provide a single tone ringing function. Using this technique, the controller must turn the audio tone on for a period of time, and then turn the audio tone off again. By repeating this process, a single tone ring is created. A more complex ringing technique includes the provision of two tones. Using this technique, a controller causes a frequency generator to bounce between two different frequencies during a first part of a ringing cycle, and then disables the frequency generator during the second part of a ringing cycle. By varying the frequencies, the ringing sound can resemble a cricket chirp, a regular telephone ring, or the like. As the processor operates to provide this ringing function, it must also process time critical events received over the air from a cellular base station.

To produce more complicated ringing sounds, manufactures have utilized additional frequency generators or more powerful processors. To play a melody as a ringing alert, the processor must keep track of which notes to play, how long to hold the notes, and how long to delay between the notes. All the while, the processor must also continuously monitor the received signal strength, control and/or paging channel messages, battery level, key presses, and other events important for the operation of a cellular telephone. Using additional frequency generators frees up some processing time; however, this technique also requires additional circuit board space—a valuable commodity. As previously mentioned, using more powerful processors increases the drain on the battery, thereby reducing talk-time and stand-by time. Thus, there is a need in the art for a technique to provide such a feature without requiring additional circuit board space or processing power.

Another short-coming of current techniques is that the number of simultaneously generated tones is limited. For complex audio sequences that include multi-part harmony, the aforementioned problems are cascaded. Thus, there is a need in the art for a method and an apparatus to reduce the processing requirements necessary to playback complex audio sequences, such as multi-part harmony melodies, within a hand-held device, such as a cellular telephone.

### SUMMARY OF THE INVENTION

The present invention solves the above-described problem by providing an apparatus and method for processing complex audio sequences by off-loading the processing requirements to a supplemental processing unit.

Generally described, the present invention provides a method for providing the playback of audio sequences within an electronic device. The electronic device includes a memory element, a host processing unit and a supplemental processing unit. In operation, the host processing unit receives and stores data that represents one or more tone patterns into the memory element. In response to detecting events (i.e., an incoming call if the electronic device is a cellular telephone), the host processing unit accesses the memory element to obtain data representing a tone pattern that is associated with the detected event. The host processing unit then provides the data to the supplemental processing unit. In one embodiment, this may be accomplished by using a shared memory element. The shared memory element may include, but is not limited to (a) RAM devices that are shared through the use of a memory access controller, (b) dual-ported RAM devices and (c) parallel ports. In another embodiment, this may be accomplished by directly interfacing to the supplemental processing unit. In either case, the supplemental processing unit converts the data representing the tone pattern into an audio sequence.

In one embodiment, the tone sequence may be large and thus, provided to the supplemental processing unit in multiple portions. In this embodiment, the host processing unit only provides a portion of the tone pattern to the supplemental processing unit. The supplemental processing unit then operates on the portion of the tone pattern and provides an indicator to the host processing unit when it is completed, or nearly completed with the first portion. In response to this indicator, the host processing unit then provides a next portion of the tone patterns to the supplemental processing unit. Advantageously, the host processing unit is only burdened by detecting the indicator from the supplemental processing unit and providing the additional data to the supplemental processing unit. Thus, the host processing unit is able to process other time-critical events without delay.

In another embodiment, the electronic device may receive and process multiple events requiring the provision of tone patterns. In this embodiment, during the playback of a first tone pattern, the host processing unit may detect an event requiring processing of an intervening tone pattern. In response to detecting such an event, the host processing unit provides an interrupt signal to the supplemental processing unit. The supplemental processing unit then interrupts the playback of the first tone pattern and begins to interact with the host processing unit to playback the intervening tone pattern. Upon completion of the playback of the intervening tone pattern, the supplemental processing unit can return to the playback of the first tone pattern.

These and other aspects, feature, and advantages of the present invention will be more clearly understood and appreciated from a review of the following detailed description of the present invention and possible embodiments thereof, and by reference to the appended drawings and claims.

### BRIEF DESCRIPTION OF THE DRAWINGS

FIG. 1 is a block diagram illustrating the functional relationship between various components of an exemplary embodiment of the present invention.

FIG. 2 is a flow diagram illustrating the operation of an exemplary embodiment of the present invention.

FIG. 3 is a functional diagram illustrating an exemplary structure for the shared memory unit illustrated in FIG. 1.

FIG. 4 is a block diagram of an alternate sound generation source.

FIG. 5 is a data structure diagram illustrating the structure of an exemplary Note Event.

FIG. 6a is a flow diagram illustrating the steps required in an exemplary embodiment to cause the supplemental processing unit to start processing Note Event data.

FIG. 6b is a flow diagram illustrating the steps required in an exemplary embodiment to stop the supplemental processing unit from processing Note Event data.

FIG. 7 is a flow diagram illustrating the operation of the supplemental processing unit processing Note Event data.

FIG. 8 is a flow diagram illustrating the details involved in an exemplary embodiment of the present invention while processing Note Events.

FIG. 9 is a flow diagram illustrating the steps performed by an exemplary embodiment of the present invention when processing each Note Event.

### DETAILED DESCRIPTION OF THE INVENTION

The present invention allows the playback of complex audio sequences within an electronic device without overburdening the host processor for the electronic device. In general, tone patterns or audio sequences are stored within a memory element accessible to the host processor. When an event occurs that requires the playback of an audio sequence, the host processor accesses the memory element to retrieve data representing at least a portion of the audio sequence. The host processor then provides this data to a supplemental processor. The supplemental processor handles the timing, conversion, and control details of the playback. This advantageously alleviates processing burdens traditionally imposed on the host processor.

Prior to describing the various embodiments and aspects of the invention, the following terms are defined:

Polyphony refers to the number of different sounds that a device can play simultaneously. For instance, if a device can play three tones at the same time, the device has a Polyphony of three.

Polyphonic means the ability to play more than one sound at the same time.

Monophonic means the ability to play only one sound at a time.

A Tone is a pattern or sequence of Note Events that can be played through a speaker. The sequence may consist of the same frequency sinusoid being turned on and off in a specific pattern or may consist of different sinusoid frequencies, or other wave forms or sound waves being turned on and off in a specific pattern. For instance, the Tone for a Polyphonic device having a Polyphony of three can have up to three sinusoids sounding at the same time. A Tone will typically be a short, repetitive type of sound.

A Note Event is the smallest sonic unit of a Tone. A Tone or Melody Ring is just a sequence of Note Events. In one embodiment of the present invention, four types of Note Events are available. These Note Events are NoteOn, NoteOff, StopSeq, and LoopSeq.

A NoteOn Note Event specifies a specific sinusoid, wave form or other sound representation to be played, the volume level at which to play the sound representation and a duration or delta time over which the note is to exist.

A NoteOff Note Event specifies a specific sinusoid, wave form or other sound representation to be played to be turned off. In a specific embodiment, a NoteOff note event may be implemented by using a NoteOn Note Event with the volume parameter set to zero or off. The NoteOff Note Event may also include a delta time to indicate a delay before the note is actually turned off.

A StopSeq Note Event identifies the end of a Tone or Melody. The StopSeq Note Event may also include a delta time to indicate a delay before the Tone or Melody ends.

A LoopSeq Note Event identifies the end of a looped sequence of Note Events and indicates that the playback of the Tone or Melody should continue at the beginning of the sequence. The LoopSeq Note Event may also include a delay or delta time that should exist prior to restarting at the beginning of the sequence.

A Melody, or a Melody Ring, is the same as a tone; however, the term Melody or Melody Ring is used to refer to a more complicated sequence of sounds and may include a recognizable song or a portion of a song.

A Melody Table is a data structure that includes data specifying a complete sequence of Note Events that make up an entire Tone or Melody. When the Tone or Melody is played, successive segments from the Melody Table are provided to the playback device.

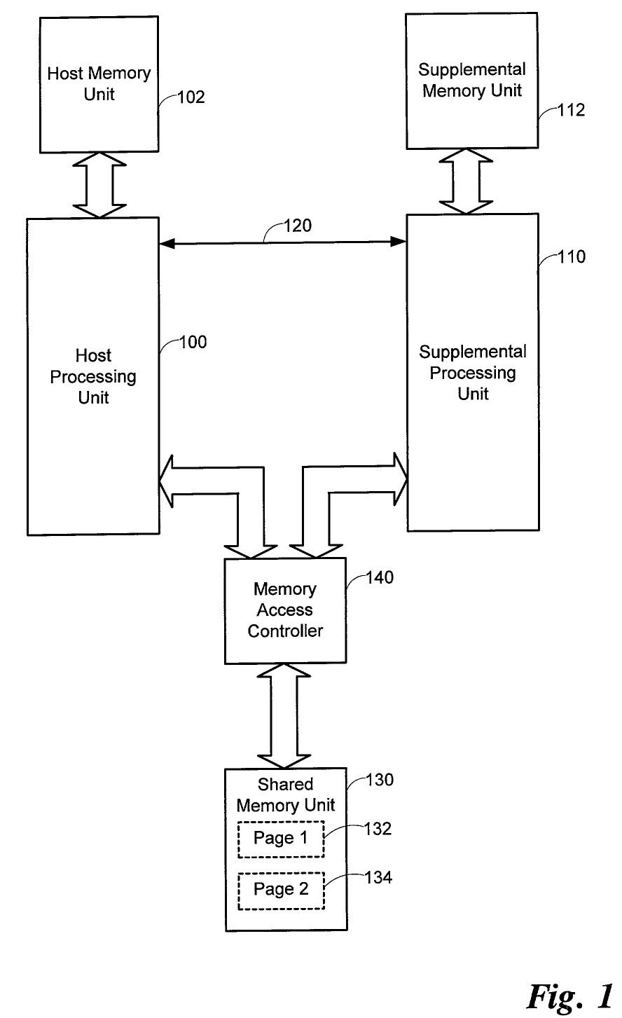

Now turning to the figures where like numerals refer to like elements throughout the several views, a detailed description of various embodiments and aspects of the present invention is described. FIG. 1 is a block diagram illustrating the functional relationship between various components of an exemplary embodiment of the present invention. A host processing unit 100 controls and monitors the operation of an electronic device within which it is embedded. For instance, in a cellular telephone, the host processing unit responsibilities may include, but are not limited to, monitoring the call processing state, processing key presses, controlling timers, controlling back-lighting, monitoring battery levels, monitoring signal strength, updating the display, and the like. During operation of the electronic device, several events may occur which require an audible alert. In response to such an event occurring, the host processing unit 100, at a very high level, initiates, monitors and controls the delivery of appropriate audible alerts. The host processing unit 100 interfaces to a host memory unit 102. In an exemplary embodiment of the invention, data representing various tone patterns or audio sequences may reside within the host memory unit 102.

A supplemental processing unit 110 controls lower level processing operations. In one embodiment, the supplemental processing unit 110 may be a digital signal processor (DSP) specifically designed to handle certain call processing, audio, or data encoding/decoding tasks. The supplemental processing unit 110 may interface with a supplemental memory unit 112. In an exemplary embodiment of the invention, data representing a currently active tone pattern or an audio sequence may reside within the supplemental memory unit 112. A control/status interface 120 ties the host processing unit 100 to the supplemental processing unit 110. Over the control/status interface 120, the host processing unit 100 and supplemental processing unit 110 can exchange status information, control information, or interrupt signals.

The illustrated embodiment includes a shared memory unit 130 having a first page 132 and a second page 134. The host processing unit 100 and the supplemental processing unit 110 may access the shared memory unit 130 through a memory access controller 140. It should be understood by those skilled in the art, that the illustrated configuration is only provided as one possible technique. Other techniques include, but are not limited to, the use of a dual ported RAM or the use of a parallel port to transfer data from the host processing unit 100 to the supplemental processing unit 110.

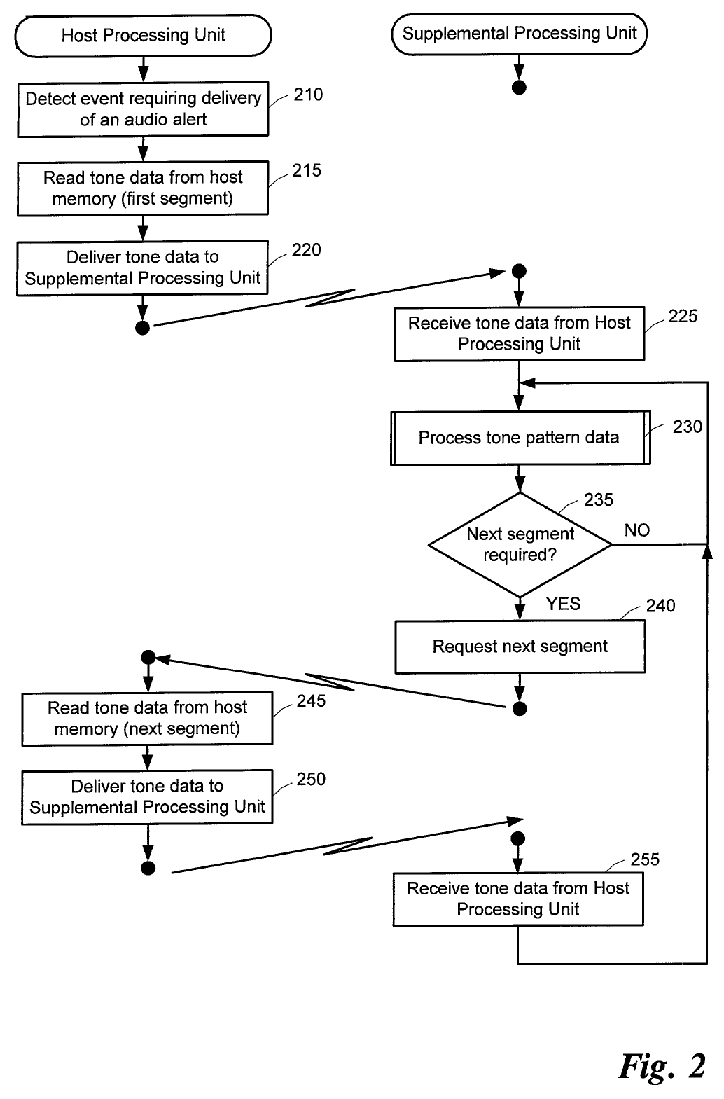

FIG. 2 is a flow diagram illustrating the operation of an exemplary embodiment of the present invention. The illustrated process identifies the operations performed by the host processing unit 100 and supplemental processing unit 110 for the download and playback of an audio sequence. Initially, the host processing unit 100 detects the occurrence of an event requiring the delivery of a playback of an audio sequence 210. The host processing unit 100 continues by accessing the host memory unit 102 to read at least a portion, or a first segment, of tone pattern data for the audio sequence 215. For short audio sequences, all of the tone pattern data may be read in a single step. Once the first segment of the tone pattern data has been read, the host processing unit 100 delivers the tone pattern data to the supplemental processing unit 110, either indirectly through the shared memory unit 130 or directly 220.

The supplemental processing unit 110 receives the tone pattern data directly from the host processing unit 100, or through the shared memory unit 130 225. The supplemental processing unit 110 then processes the tone pattern data to generate the desired audio sequence 230. If the tone pattern data received by the supplemental processing unit 110 is only one segment of multiple segments, then when the supplemental processing unit 110 completes processing the tone pattern data for the current segment 235, the supplemental processing unit 110 will request the host processing unit 100 to send the next segment 240. Alternatively, the host processing unit 100 may monitor the supplemental processing unit 110 or a status register to determine when the next segment should be downloaded to the supplemental processing unit 110.

In either case, the host processing unit 100 continues by accessing the host memory unit 102 to read the next segment, or final segment of tone pattern data for the audio sequence 245. Again, the host processing unit 100 delivers the tone pattern data to the supplemental processing unit 110, either indirectly through the shared memory unit 130 or directly 250. The supplemental processing unit 110 receives the next and/or final segment of the tone pattern data from the host processing unit 100, or through the shared memory unit 130 255 and continues by processing the tone pattern data 230.

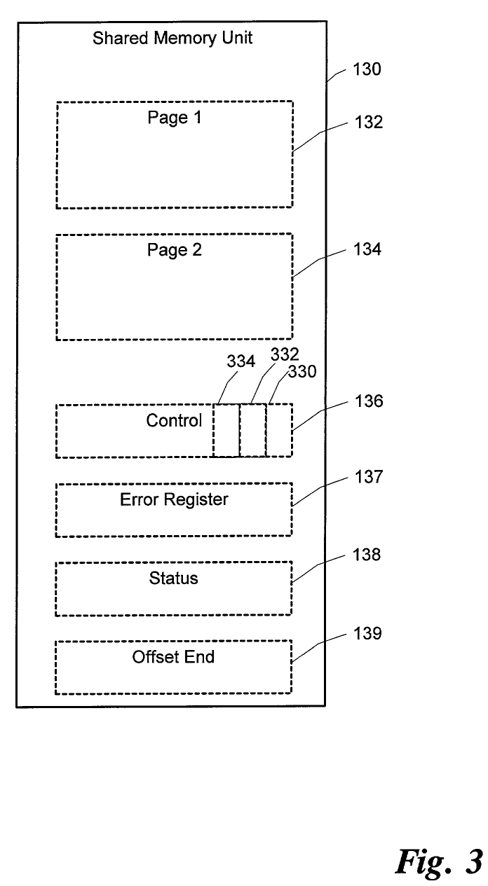

FIG. 3 is a functional diagram illustrating an exemplary structure for the shared memory unit 130. The shared memory unit 130 includes two memory pages, page 1 132 and page 2 134. In addition, a control register 136 and a status register 138 are provided to pass control and status information between the host processing unit 100 and the supplemental processing unit 110. In an exemplary embodiment of the present invention, the control register 136 includes a START_BIT 330, a STOP_BIT 332 and a LOOP_BIT 334.

The START_BIT 330 and the STOP_BIT 332 provide direct control over the operation of the supplemental processing unit 110. If the START_BIT 330 is set (i.e., has a value of “1”), the supplemental processing unit 110 will begin processing tone pattern data at the beginning of the first shared memory page 132. As long as the STOP_BIT 332 is cleared (i.e., has a value of “0”), the supplement processing unit 110 will continue processing the tone pattern data. However, if the STOP_BIT 332 is set, the supplemental processing unit 110 will discontinue processing the tone pattern data and turn off any currently sounding tones. At reset, the START_BIT 330 and the STOP_BIT 332 are cleared.

The LOOP_BIT 334 controls the operation of the supplemental processing unit upon encountering a stop or loop event in the tone pattern data. If the LOOP_BIT 334 is set, upon encountering a stop or loop event in the tone pattern data, the supplemental processing unit 110 will continue processing the tone data at the beginning of the first shared memory pageor buffer. If the LOOP_BIT 334 is cleared, upon encountering a stop or loop event in the tone pattern data, the supplemental processing unit 110 will stop processing tone data. At reset, the LOOP_BIT 334 is cleared.

The various sounds within a Tone or Melody can be generated from a variety of sources. An exemplary embodiment of the present invention may include a digital signal processor chip (DSP) to generate the sounds. Such a DSP could include a DTMF engine to generate DTMF tones by summing together two sinusoids of different frequencies and amplitudes, or generate single frequency tones.

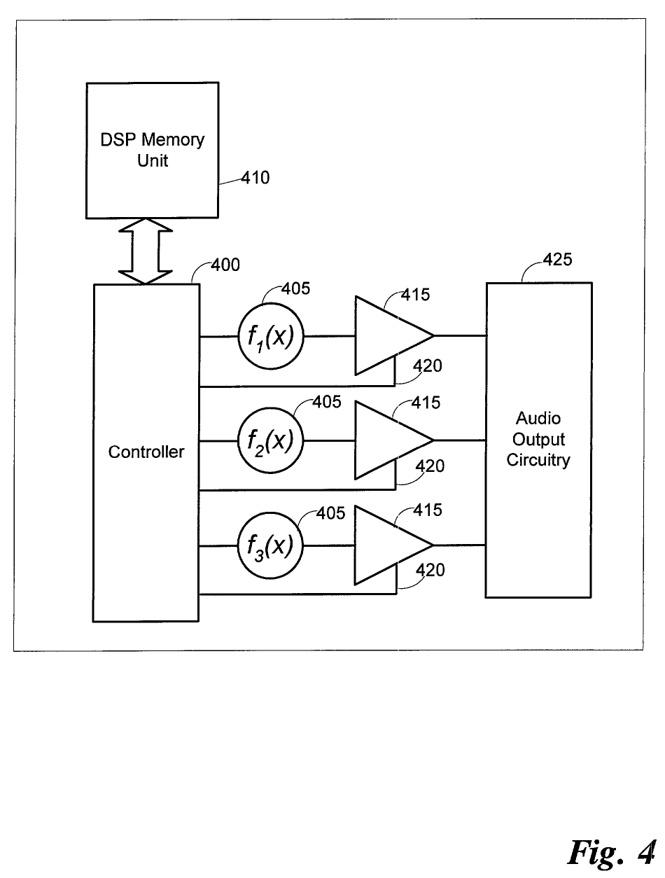

FIG. 4 is a block diagram of an alternate sound generation source. In this embodiment, controller 400 controls the operation of several wave form generators 405. The controller accesses a DSP memory unit 410 to obtain Note Events, as well as particular information about the sounds, frequencies, volumes, or the like to be generated. The wave form generators 405 could be any type of wave form generator including sinusoidal, saw-tooth, square wave, triangular, or some other type of wave form generator. In an alternate embodiment, the wave form generators may be replaced with WAV file players, MP3 converters, or any other type of sound generation device. The output of each wave generator 405 is provided to a volume controller 415. The controller 400 can control the output volume of each volume controller 415 with a volume adjust control line 420. The output of each volume controller 415 is provided to an audio output circuitry 425 which, among other things will include a speaker.

In an exemplary embodiment, two Tone Buffers are used to transfer blocks or segments of Note Events from the host processing unit 100 to a supplemental processing unit 110. The use of two Tone Buffers allows the host processing unit 100 to send segments of Note Events to the supplemental processing unit 110 rather than having to independently send each Note Event. Advantageously, this aspect of this embodiment of the invention allows the host processing unit 100 provide the playback of complex Tones and Melodies without overburdening the host processing unit 100. This advantage can best be illustrated in conjunction with a particular example.

In the described example, each Tone Buffer of two Tone Buffers holds 35 Note Events for a device having a Polyphony of three. In an embodiment in which each Note Event requires seven (7) bytes of memory, each Tone Buffer will have a size of 245 bytes. Assuming that the fastest note that can be played is a sixteenth note, and that the fastest tempo is 172 beats per minute, each beat will last 0.348 seconds (60 seconds/172 beats per minute). With one beat being equal to a quarter note, the duration of a single sixteenth note is 87 milliseconds. If the Tone Buffer is loaded with 35 NoteOn Note Events, eleven Note Events for each of the three channels, the playback time would last approximately 0.959 seconds (87 milliseconds * 11). Thus, in this worst case example, the host processing unit 100 is only required to load a Tone Buffer every 0.959 seconds.

Storage Format for Tones and Melodies

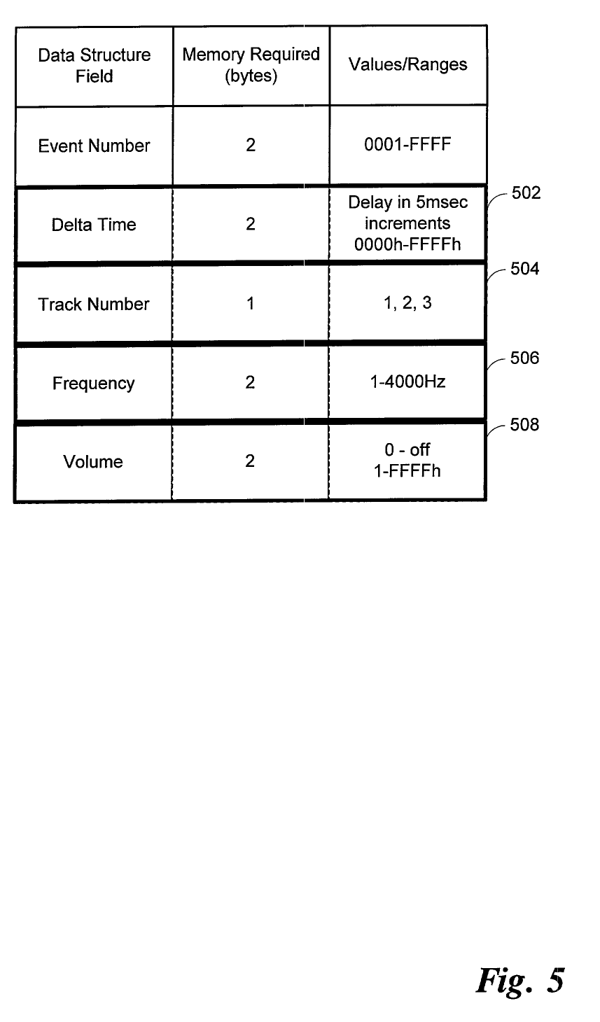

A Tone will be stored in memory as a sequence of Note Events (NoteOn's and Noteoff's). In an exemplary embodiment, each Note Event will requires seven (7) bytes of information. FIG. 5 is a data structure diagram illustrating the structure of an exemplary Note Event. The DeltaTime field 502 is a two byte field defining the amount of time, or the duration, between this Note Event and the Note Event immediately preceding this Note Event. The range of values for the DeltaTime field 502 is 0 to 0FFFFh (0 to 65,535). For a typical embodiment in which each clock tick requires 5 milliseconds, this translates into a range of 0 seconds to 327.675 seconds. The TrackNumber 504 is a single byte field identifying which channel or generator should be used for sounding the Note Event. In an embodiment having three channels, the TrackNumber can have a value of 1, 2 or 3. The Frequency field 506 is a two byte field identifying the sound or wave form to be generated. In an exemplary embodiment, the Frequency field 506 specifies the sinusoid frequency in hertz. In this embodiment, the range of values in the Frequency field 506 is 1 to 4000. A value of zero in the Frequency field 506 has special meaning. If the Frequency field 506 is zero or cleared, then the Note Event may be a StopSeq Note Event or a LoopSeq Note Event. The actual interpretation of such a Note Event is dependent upon the state of the LOOP_BIT 334 in the control register 136. If the LOOP_BIT 334 is set, then a Note Event with the Frequency field 506 having a value of zero is a LoopSeq Note Event. Otherwise, the Note Event is a StopSeq Note Event. The Volume field 508 is a two byte field and specifies the volume for a particular note on a particular track. A value of zero in the Volume field 508 has special meaning. If the Volume field 508 is zero, then the Note Event is a NoteOff Note Event. Otherwise, the Note Event is a NoteOn Note Event. Thus, the only difference between the NoteOn and a NoteOff Note Events is the value of the Volume field 508. A NoteOff must have a Volume of zero, whereas a NoteOn can have any permissible volume except zero. In the exemplary embodiment, the supplemental processing unit 110 is capable of playing successive NoteOn Note Events without requiring a NoteOff Note Event in between them. A melody implemented without any, or with only a few NoteOff Note Events will have a legato or smooth sound.

Note Event Types

More specifically, the exemplary embodiment allows for four possible types of Note Events: NoteOn, NoteOff, StopSeq, and LoopSeq. Each Note Event type is seven (7) bytes long. The settings of the Frequency field 506, the Volume field 508, and the LOOP_BIT 334 distinguish these four different Note Event types. The distinguishing characteristics for each Note Event type are summarized as:

NoteOn—the Frequency field 506 and the Volume field 508 are non-zero and the setting of the LOOP_BIT 334 is irrelevant.

NoteOff—the Frequency field 506 is non-zero, the Volume field 508 is zero and the setting of the LOOP_BIT 334 is irrelevant.

StopSeq the Frequency field 506 is zero, the Volume field 508 is non-zero and the LOOP_BIT 334 is cleared.

LoopSeq—the Frequency field 506 is zero, the Volume field 508 is non-zero and the LOOP_BIT 334 is set.

Table 1 summarizes field ranges for the four possible event types in the exemplary embodiment.

TABLE 1

| | Delta Time | Track Number | Frequency | Volume |
|---|---|---|---|---|
| NoteOn | 0 <= x <= | 1,2, or 3 | 1 <= X <= | 1 <= x <= |
| | 65535 | | 4000 | 65535 |
| NoteOff | 0 <= x <= | 1,2, or 3 | 1 <= X <= | 0 |
| | 65535 | | 4000 | |
| StopSeq | 0 <= x <= | 1,2, or 3 | 0* | 1 <= x <= |
| | 65535 | | | 65535 |
| LoopSeq | 0 <= x <= | 1,2, or 3 | 0** | 1 <= x <= |
| | 65535 | | | 65535 |

*LOOP_BIT = 0 in ToneControlRegister
**LOOP_BIT = 1 in ToneControlRegister

Referring again to FIG. 3, specific details for an exemplary embodiment suitable for the present invention are described. As previously mentioned, two Tone Buffers, along with a Control register 136, a Status register 138, an Error register 137, and an OffsetEnd register 139 are provided.

Each Tone Buffer resides in a 256×16-bit word block in the shared memory unit 130 accessible by both the host processing unit 100 and the supplemental processing unit 110. The two Tone Buffers are contiguous and are each 245 bytes long. A length of 245 bytes will hold 35 Note Events (7 bytes/event * 35 events=245 bytes). When a Melody is started, the supplemental processing unit starts playing Note Events at the beginning of the first Tone Buffer or Page 1 132 of the shared memory unit 130. When the supplemental processing unit 110 reaches the end of the first Tone Buffer, the supplemental processing unit may generate an interrupt to the host processing unit 100 and then continue processing from the second Tone Buffer. Similarly, when the supplemental processing unit 110 reaches the end of the second Tone Buffer, the supplemental processing unit 110 may generate an interrupt to the host processing unit 100 and then continue playing from the first Tone Buffer. Table 2 illustrates how the Note Events exist in the two Tone Buffers.

TABLE 2

| | Byte | |
|---|---|---|
| | Offset | |
| | (hex) | Description |
| Buffer | 0 | Note On/Off event # 1 (Delta Time, Track Number, |
| #1 | | Frequency, Volume) |
| | 7 | Note On/Off event # 2 (Delta Time, Track Number, |
| | | Frequency, Volume) |
| | ... | ... |
| | ... | ... |
| | EE | Note On/Off event # 35 (Delta Time, Track Number, |
| | | Frequency, Volume) |
| Buffer | F5 | Note On/Off event # 36 (Delta Time, Track Number, |
| #2 | | Frequency, Volume) |
| | ... | ... |
| | ... | ... |
| | ... | ... |
| | 1E3 | Note On/Off event # 70 (Delta Time, Track Number, |
| | | Frequency, Volume) |

The Control register 136 is used to control how the supplemental processing unit 110 plays the Note Events in the Tone Buffers. The operation of the Control register 136 was described above in conjunction with FIG. 3. The Status register 138 indicates the status of the Tone being played. Table 3 provides a summary of the bit fields and their meaning for the Status register 138.

TABLE 3

| Bit | Name | Description |
|---|---|---|
| 31-4 | Reserved | |
| 3 | ERROR_BIT | Indicates that the supplemental |
| | | processing unit 110 has encountered a |
| | | problem. The error code will be stored |
| | | in the Error register 139. The |
| | | ERROR_BIT is set when an error is |
| | | encountered and cleared other wise. |
| | | Upon reset this bit is cleared. |
| 2-1 | BOUNDARY_STATUS | Indicates that the supplemental |
| | | processing unit 110 has crossed a Tone |
| | | Buffer boundary. The following settings |
| | | have the corresponding meanings: |
| | | 00 - A Tone Buffer boundary has not |

been crossed

01 - The supplemental processing unit

110 has crossed the end of the first
Tone Buffer

10 - The supplemental processing unit

110 has crossed the end of the
second Tone Buffer

| | | |
|---|---|---|
| | | 11 - Reserved |
| | | Upon reset, this field is cleared. |
| | | Note: When the supplemental |
| | | processing unit 110 crosses the end of |
| | | a buffer, the supplemental processing |
| | | unit 110 sets the appropriate bit and |
| | | clears the other bit. For example, when |
| | | the supplemental processing unit 110 |
| | | crosses the end of the first Tone Buffer, |
| | | the supplemental processing unit sets |
| | | the bits to 01. |
| 0 | ENGINE_STATUS | Indicates whether the supplemental |
| | | processing unit is stopped or is playing. |
| | | 1 - supplemental processing unit 110 is |

playing

0 - supplemental processing unit 110 is

stopped

Upon reset, the value of this bit is
cleared.

The Error register 137 contains the error code that caused the ERROR_BIT 332 to be set in the Status register 138. Table 4 provides a summary of the bit fields and their meaning for the Error register 137.

TABLE 4

| Bit | Name | Description |
|---|---|---|
| 31:0 | Error Codes | Indicates reason that the ERROR_BIT was set in |
| | | the Status register 138. |
| | | 1 = Invalid Frequency |
| | | 2 = Invalid Delta Time |
| | | 3 = Invalid Volume |
| | | 4 = Invalid Track Number |
| | | Upon reset, the values of this register are cleared. |

The OffsetEnd register 139 specifies the supplemental processing unit's 110 current offset in the Tone Buffer when the supplemental processing unit 110 stops (upon reaching the end of a Tone or by the host processing unit 100 setting the STOP_BIT in the Control register 136. The offset specifies the last Note Event that was played by the supplemental processing unit 110. For example, if the supplemental processing unit 110 is stopped after it processes the first Note Event in the current Tone Buffer, the offset value in the OffsetEnd register 139 is zero. As another example, if the supplemental processing unit 110 is stopped after it has processed the last (35^{th}) Note Event in the current Tone Buffer, the offset value in the register is 34₁₀ or 22₆.

Using the OffsetEnd register 139 with the BOUNDARY_STATUS bits in the Status register 138, the host processing unit 100 can determine the exact location where the supplemental processing unit 110 stops. The host processing unit 100 can use this location information for handling cases where one Tone (e.g. Low Battery Warning) temporarily interrupts another Tone (e.g. Melody Ring Tone). The values in the OffsetEnd register 139 are valid only when the supplemental processing unit 110 is stopped. In other words, the supplemental processing unit 110 updates this register only when the supplemental processing unit 110 stops processing Note Events or is stopped by the host processing unit 100. Table 5 summarizes the bit fields and their meaning for the OffsetEnd register 139.

TABLE 5

| Bit | Name | Description |
|---|---|---|
| 31:6 | Reserved | |
| 5:0 | Offset | Specifies the last Note Event that was played (in the |
| | | current Tone Buffer) when the supplemental |
| | | processing unit 110 stops or is stopped. The offset |
| | | specifies the last Note Event that was played by the |
| | | supplemental processing unit. |
| | | 0x00 <= Offset <= 0x22 |
| | | Upon reset, this field is cleared. |

Referring again to FIG. 2, the details of various steps or processes are described. The supplemental processing unit 110 reads the Note Event data from the Tone Buffers 132 134 and generates the appropriate sinusoids or other wave forms at the desired times. In an exemplary embodiment, the supplemental processing unit 110 uses a 5 millisecond timer along with the DeltaTime field 502 to determine how long to wait before each Note Event should be processed. Due to the use of a 5 millisecond timer, all DeltaTimes will be rounded to the nearest 5 millisecond increment. This rounding should not be noticeable when the melody is played.

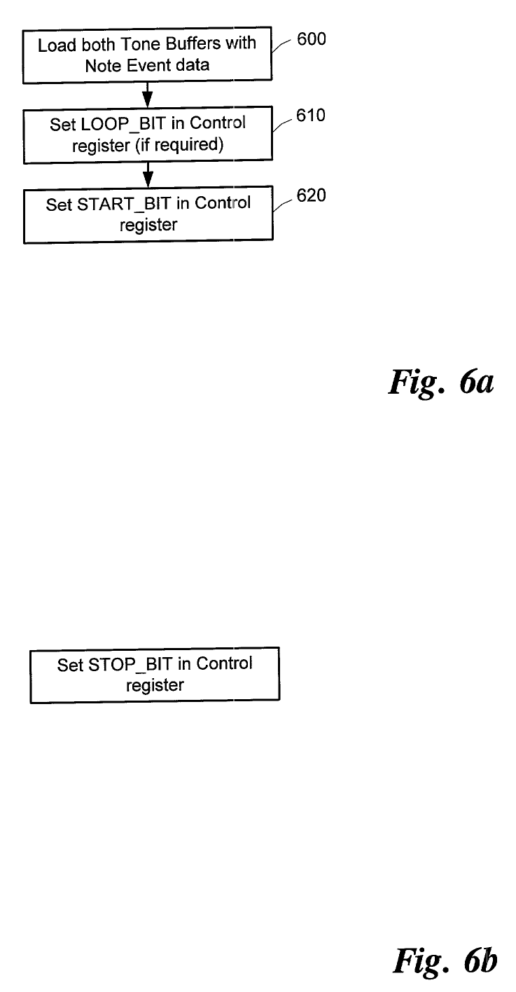

FIG. 6a is a flow diagram illustrating the steps required in an exemplary embodiment to cause the supplemental processing unit to start processing Note Event data. In comparing FIG. 6a with FIG. 2, the steps illustrated in FIG. 6a would be performed in step 220 of FIG. 2. Initially, the host processing unit 100 loads Note Event data into both of the Tone Buffers 600, assuming that the desired audio sequence requires the entire memory. Once the Tone Buffers are loaded, the host processing unit 100 sets the LOOP_BIT 334 in the Control register 136 if required 610 and then sets the START_BIT in the Control register 136 620.

FIG. 6b is a flow diagram illustrating the steps required in an exemplary embodiment to stop the supplemental processing unit from processing Note Event data. To stop the supplemental processing unit 110, the host processing unit 100 sets the STOP_BIT 332 in the Control register 136 630.

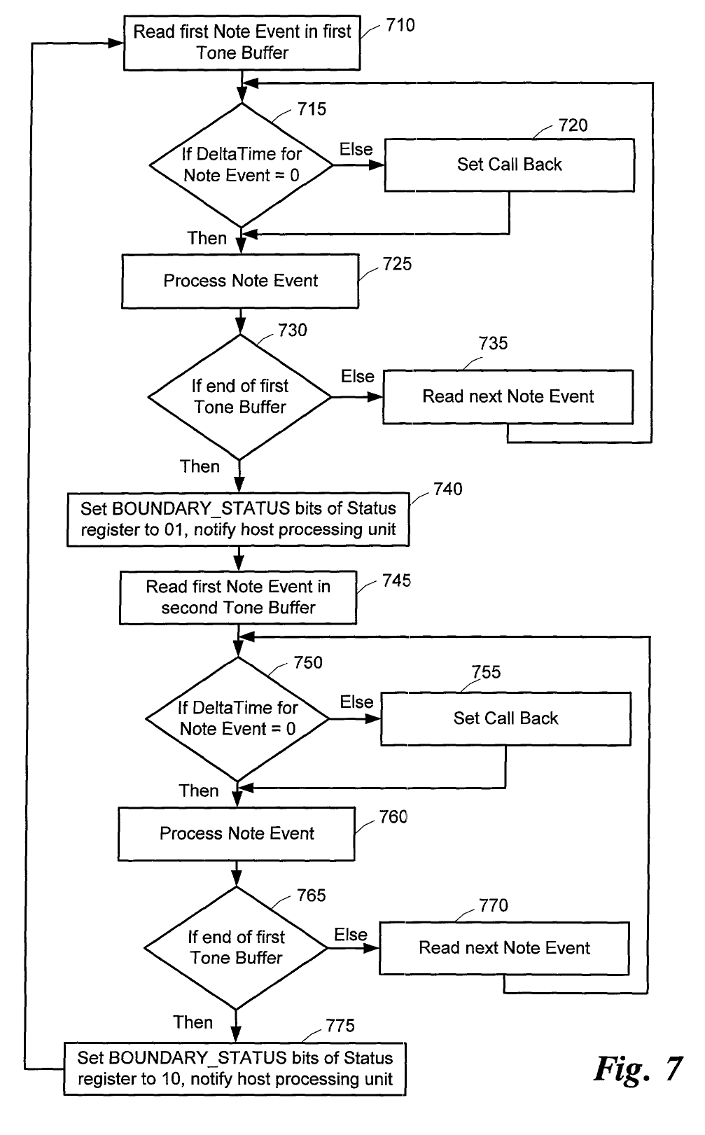

FIG. 7 is a flow diagram illustrating the operation of the supplemental processing unit processing Note Event data. Once the supplemental processing unit 110 receives notice from the host processing unit 100 to begin processing Note Events (i.e., FIG. 6a), the supplemental processing unit 110 reads the first Note Event from the first Tone Buffer (i.e., see Table 2) 710. The supplemental processing unit 110 then examines the DeltaTime field 502 of the first Note Event. If the DeltaTime field 502 of the Note Event is equal to zero 715, indicating that there is no delay before processing the Note Event, then the Note Event will be processed 725. If the DeltaTime field 502 of the first Note Event is not equal to zero 715, then a call back timer is set 720. The call back timer can be implemented using a variety of techniques and the present invention should not be limited to any particular technique. One such technique is to simply enter a delay loop based on the value of the DeltaTime field 502. Once the delay has expired, the Note Event can be processed 725. Another technique is to schedule an interrupt event to occur at a time based on the value of the DeltaTime field 502. Upon the occurrence of the interrupt, the Note Event can be processed 725. Those skilled in the art will recognize that the supplemental processing unit 110 could continue to read the Note Events from the Tone Buffer while waiting for the delay to expire or the interrupt to occur. Thus, several Note Events could be posted and pending processing at the same time.

Regardless of the technique used, the Note Event is processed at the appropriate time 725. After processing the Note Event, if the end of the first Tone Buffer has not been reached 730, the supplemental processing unit 110 will read the next Note Event from the first Tone Buffer 735. Processing will then resume with step 715 with the next Note Event. However, if the end of the first Tone Buffer has been reached 730, the supplemental processing unit 110 will set the Set BOUNDARY_STATUS bits of Status register 138 to “01” and notify the host processing unit 100 that the status has changed 740. The notice to the host processing unit 100 could be provided in the form of an interrupt, function call, status line, or some other technique and the present invention should not be limited to any particular technique.

As long as the supplemental processing unit 110 has not been instructed to stop, it will continue processing Note Events by reading the first Note Event in the second Tone Buffer 745. The supplemental processing unit 110 then examines the DeltaTime field 502 of this Note Event. If the DeltaTime field 502 of the this Note Event is not equal to zero 750, then a call back timer is set 755 prior to processing the Note Event 760. Otherwise, the Note Event is immediately processed 760. After processing the Note Event, if the end of the second Tone Buffer has not been reached 765, the supplemental processing unit 110 will read the next Note Event from the second Tone Buffer 770. Processing will then resume at step 750 with the next Note Event. However, if the end of the second Tone Buffer has been reached 765, the supplemental processing unit 110 will set the Set BOUNDARY_STATUS bits of Status register 138 to “10” and notify the host processing unit 100 that the status has changed 775. As long as the host processing unit 100 has not stopped the supplemental processing unit 110, the supplemental processing unit 110 will return to step 710 and again process Note Events from the first Tone Buffer. It should be understood by the reader that while the supplemental processing unit 110 is processing Note Events from one of the Tone Buffers, the host processing unit 100 can be loading new Note Events into the other Tone Buffer. Thus, a continuous stream of Note Events can be fed to the supplemental processing unit 110.

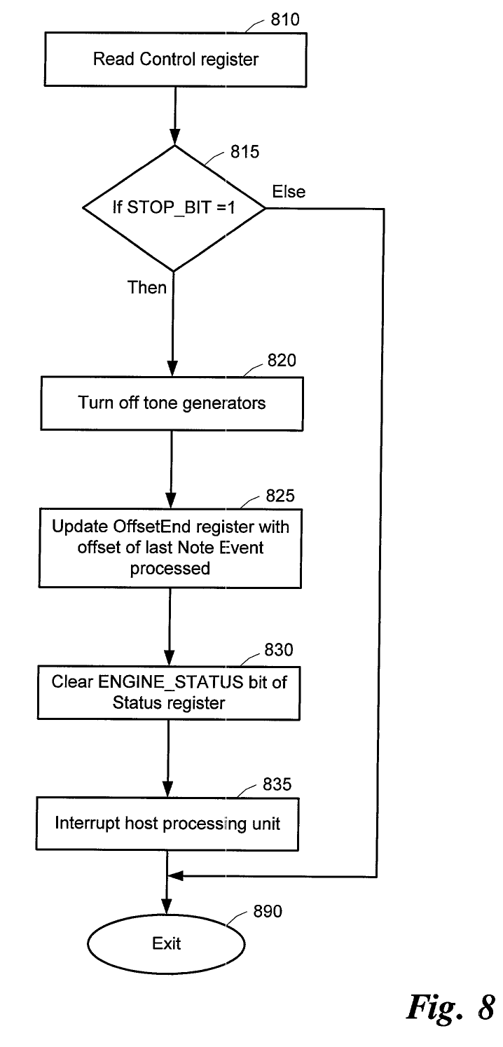

FIG. 8 is a flow diagram illustrating the details involved in an exemplary embodiment of the present invention while processing Note Events. In an exemplary embodiment, the steps illustrated in the flow diagram of FIG. 8 may occur at any time the supplemental processing unit 110 is processing Note Events. In alternative embodiments, certain restrictions may be imposed upon the supplemental processing unit so that the steps illustrated in FIG. 8 can only be performed during certain operating windows. During operation, the supplemental processing unit 110 will periodically examine the Control register 136 810. Alternatively, the supplemental processing unit 110 may examine the Control register 136 in response to an interrupt event 810. In either technique, if the STOP_BIT of the Control register 136 is clear 815, then the supplemental processing unit 110 continues processing Note Events as usual 890. However, if the STOP_BIT of the Control register 136 is set 815, then the supplemental processing unit 110 turns off the tone generators 820. Next the supplemental processing unit 110 updates the OffsetEnd register 139 with the offset value for the last Note Event processed 825. The supplemental processing unit 110 then clears the ENGINE_STATUS bit in the Status register 138 to indicate that the supplemental processing unit 110 has stopped processing Note Events 830. Finally, the supplemental processing unit 110 notifies the host processing unit that the operating status has changed. In an exemplary embodiment, this is performed by issuing an interrupt 835.

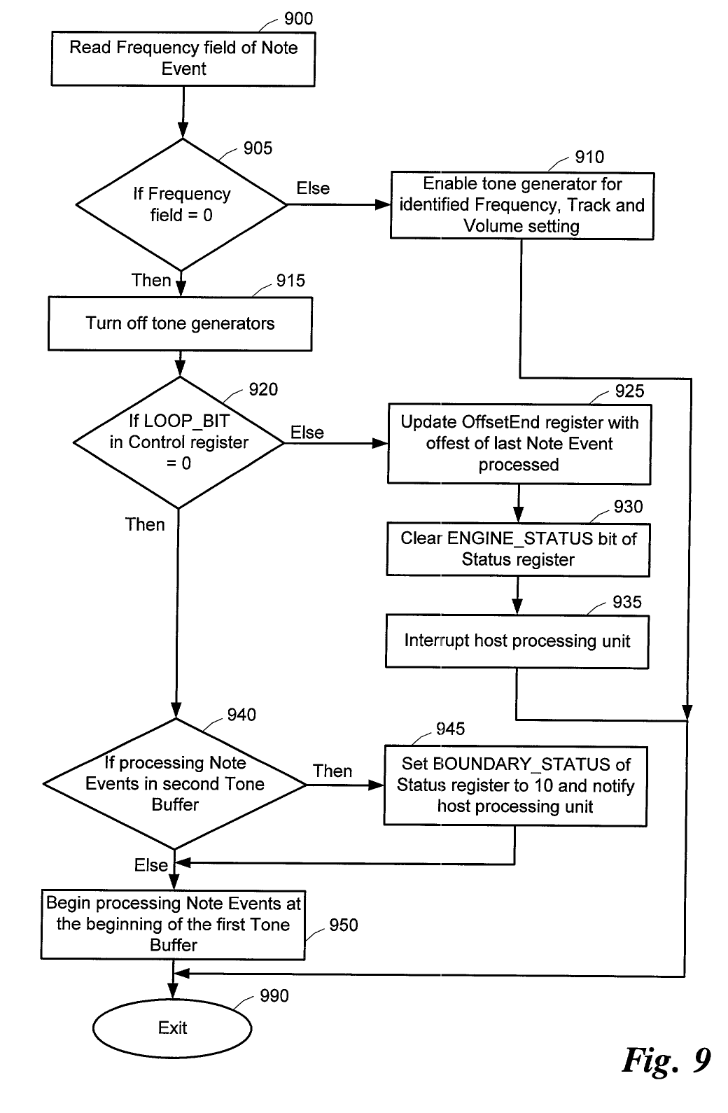

FIG. 9 is a flow diagram illustrating the steps performed by an exemplary embodiment of the present invention when processing each Note Event. For each Note Event, the Frequency field 506 is examined 900. If the value of the Frequency field 506 is not equal to zero 905, then the supplemental processing unit 110 turns on the appropriate tone generator, at the identified frequency and volume level 910. However, if the value of the Frequency field 506 is equal to zero 905, then the Note Event is either a StopSeq or a LoopSeq Note Event. For either case, the supplemental processing unit 110 turns off each of the tone generators 915. Next the LOOP_BIT in the Control register 136 is examined. If the LOOP_BIT is set 920, then the Note Event is a StopSeq Note Event. When a StopSeq Note Event is detected, the supplemental processing unit 110 updates the OffsetEnd register 139 with offset value of the last Note Event processed 925. Next, the supplemental processing unit 110 clears the ENGINE STATUS bit of Status register 930. Finally, the supplemental processing unit 110 notifies the host processing unit 100 that the operating status has changed 935.

If the LOOP_BIT 334 is cleared 940, then the Note Event is a LoopSeq Note Event. When a LoopSeq Note Event is detected, the supplemental processing unit 110 determines which Tone Buffer is currently being processed. If the second Tone Buffer is being processed 940, then the supplemental processing unit 110 sets the BOUNDARY_STATUS of Status register to the value “10” and notifies host processing unit 945. After setting the BOUNDARY_STATUS 945, or if the first Tone Buffer is being processed 940, the supplemental processing unit 110 begins processing Note Events at the beginning of the first Tone Buffer.

### EXAMPLES OF OPERATION

An exemplary embodiment of the present invention can generate a Legato style sound. To perform this task, successive NoteOn events without a NoteOff Events in between them should be programmed into the Melody. Reducing or eliminating the NoteOff events in the melody provides for a legato or smooth sounding melody. Table 6 illustrates a series of Note Events that can be used to generate a legato Melody. Table 6 shows Note Events that sound successive octaves of a pitch that are each played for a one second period of time. There is no silence between notes due to a NoteOff Note Event, and thus, a legato sound can be produced.

TABLE 6

| Event # | Event Type | Delta Time | Track # | Freq. | Volume |
|---|---|---|---|---|---|
| 1 | NoteOn | 0 | 1 | 220 | 1000 |
| 2 | NoteOn | 200 | 1 | 440 | 1000 |
| 3 | NoteOn | 200 | 1 | 880 | 1000 |
| 4 | NoteOn | 200 | 1 | 440 | 1000 |
| 5 | NoteOn | 200 | 1 | 220 | 1000 |
| 6 | StopSeq | 200 | 1 | 0 | 1000 |

An exemplary embodiment of the present invention can generate a staccato style sound. To get create a staccato sounding melody, the NoteOn Note Events are limited to a short duration with periods of silence between the Note Events. The periods of silence can be obtained by placing NoteOff Note Events between the NoteOn Note Events. Table 7 shows and example of this technique. Notice that the melody in Table 7 has the same notes and the same overall duration as the melody in Table 6. The only difference between these melodies is the length of time that each note is sounded.

TABLE 7

| Event # | Event Type | Delta Time | Track # | Freq. | Volume |
|---|---|---|---|---|---|
| 1 | NoteOn | 0 | 1 | 220 | 1000 |
| 2 | NoteOff | 20 | 1 | 220 | 0 |
| 3 | NoteOn | 180 | 1 | 440 | 1000 |
| 4 | NoteOff | 20 | 1 | 440 | 0 |
| 5 | NoteOn | 180 | 1 | 880 | 1000 |
| 6 | NoteOff | 20 | 1 | 880 | 0 |
| 7 | NoteOn | 180 | 1 | 440 | 1000 |
| 8 | NoteOff | 20 | 1 | 440 | 0 |
| 9 | NoteOn | 180 | 1 | 220 | 1000 |
| 10 | StopSeq | 20 | 1 | 0 | 1000 |

In some situations, it is necessary for one Tone to be temporarily interrupted or overridden by another Tone. The present invention allows such a function without over burdening the host processing unit 100. Utilizing the basic control and status features described herein, a higher level program module can be constructed to stop the playback of a first tone, identify the point at which the playback was stopped, begin the playback of a second tone, and upon conclusion of the second tone, resume the first tone at the point at which it was stopped.

Some devices, such as a cellular telephone, may require a continuous key tone function. The continuous key tone function involves playing a tone for as long as a user holds a key down. The present invention can meet the requirements for providing a continuous key tone function. To provide a continuous key tone, a NoteOn Note Event followed by a StopSeq Note Event with maximum DeltaTime are placed at the beginning of Tone Buffer. This Tone will sound until the supplemental processing unit 110 is shut down or the DeltaTime expires, whichever comes first. The maximum DeltaTime (65535) will give a delay of almost 328 seconds before the tone stops, meaning that the longest continuous key tone that can be supported is 328 seconds, almost 5.5 minutes. Table 8 shows an exemplary Note Event sequence to provide a continuous key tone for a frequency of 220 Hz.

TABLE 8

| Event # | Event Type | Delta Time | Track # | Freq. | Volume |
|---|---|---|---|---|---|
| 1 | NoteOn | 0 | 1 | 220 | 1000 |
| 2 | StopSeq | 65535 | 1 | 0 | 1000 |

The present invention also contemplates other aspects to improve the ability to play complex audio sequences in an electronic device. One such aspect is to utilize larger tone buffers. By increasing the size of the tone buffer, the processing burden placed on the host processing unit can be reduced. Another technique is to increase the polyphony of the device. This can be accomplished by adding more tone generators to permit more complex melodies. Utilizing 16 tone generators would provide the same capabilities available in the sound cards introduced in the mid 1990's.

Currently all Notes are derived from a sinusoid wave table. In one embodiment of the present invention, additional wave tables can be added to increase the richness of the melodies. For example, saw-tooth and square-wave shapes could be added into the wave tables. For a given melody, then, each tone generator would be assigned to one of the wave shapes. In yet another embodiment, downloadable wave shapes could be utilized. The wave shapes could then be stored in RAM, not ROM. This embodiment of the invention allows the user to select from an infinite number of waveforms.

In another embodiment, the 128 sounds available within the General MIDI specification could be utilized. In this embodiment, the DSP (or some combination of the Microprocessor/DSP) could play Standard MIDI files. This embodiment makes it very easy to allow the user to download and play any of the thousands of MIDI files that can be found on the Internet.

The present invention has been described in relation to particular embodiments which are intended in all respects to be illustrative rather than restrictive. Those skilled in the art will understand that the principles of the present invention may be applied to, and embodied in, hardware, software, or a combination of both, for operation on differing types of devices, regardless of the application.

Alternate embodiments will become apparent to those skilled in the art to which the present invention pertains without departing from its spirit and scope. Accordingly, the scope of the present invention is described by the appended claims and supported by the foregoing description.

What is claimed is:

1. A method for providing the playback of an audio sequence within an electronic device, the electronic device including a memory element, a first processing unit and a second processing unit, the method comprising the steps of:
(a) storing data representing a preset tone pattern into the memory element;
(b) accessing the memory element with the first processing unit and obtaining a first portion of the preset tone pattern data;
(c) providing the first portion of the preset tone pattern data obtained by the first processing unit to the second processing unit; and
(d) the second processing unit providing a playback of the first portion of the preset tone pattern data.

2. A method for providing the playback of audio sequences within an electronic device, the electronic device including a memory element, a first processing unit and a second processing unit, the method comprising the steps of:
(a) storing data representing a plurality of preset tone patterns into the memory element;
(b) accessing the memory element with the first processing unit to obtain data representing a first portion of a particular one of the plurality of preset tone patterns;
(c) providing the data representing the first portion of the particular one of the plurality of preset tone patterns to the second processing unit; and
(d) the second processing unit converting the data representing the first portion of the particular one of the plurality of preset tone patterns into an audio sequence.

3. The method of claim 2, further comprising the steps of:
providing an indicator to the first processing unit when the second processing unit has completed converting the first portion of the particular one of the plurality of preset tone patterns;
accessing the memory element with the first processing unit to obtain data representing a next portion of the particular one of the plurality of preset tone patterns; and
continuing at step (c) with the next portion.

4. The method of claim 2, further comprising the steps of providing a playback of the audio sequence.

5. The method of claim 4, further comprising the steps of:
receiving an indicator at the first processing unit, the indicator requiring processing of an intervening tone pattern of the plurality of tone patterns;
in response to receiving the indicator at the first processing unit, providing an interrupt signal to the second processing unit;
in response to receiving the interrupt signal at the second processing unit, interrupting the playback of the audio sequence;
accessing the memory element with the first processing unit to obtain data representing a first portion of the intervening tone pattern of the plurality of preset tone patterns;
providing the data representing the first portion of the intervening tone pattern of the plurality of preset tone patterns to the second processing unit;
the second processing unit converting the data representing the first portion of the intervening tone pattern of the plurality of preset tone patterns into an audio sequence; and
providing the playback of the audio sequence.

6. The method of claim 5, further comprising the steps of:
resuming the playback of the particular one of the plurality of tone patterns upon completing the play back of the audio sequence for the intervening tone pattern.

7. A method for reducing the processing requirements of a first processing unit in providing the playback of an audio sequence within an electronic device by off loading processing to a second processing unit, the electronic device including a shared memory element that the first processing unit and the second processing unit can access, the method comprising the steps of:
storing data representing a preset tone pattern into a first memory element accessible by the first processing unit;
the first processing unit,
detecting an event that requires the playback of an audio sequence;
reading a first portion of the preset tone pattern data from the first memory element;
storing the first portion of the preset tone pattern data into a first section of the shared memory element;
the second processing unit,
accessing the first portion of the shared memory element to retrieve the first portion of the preset tone pattern data; and
converting the preset tone pattern data into an audio sequence.

8. A method for reducing the processing requirements of a first processing unit in providing the playback of an audio sequence within an electronic device by off loading processing to a second processing unit, the electronic device including a shared memory element that the first processing unit and the second processing unit can access, the method comprising the steps of:
the first processing unit,
detecting an event that requires the playback of an audio sequence; and
providing a first portion of data representing a preset tone pattern to the second processing unit;
the second processing unit,
sequentially converting the preset tone pattern data into an audio sequence; and
providing an indicator to the first processing unit when a second portion of data representing the preset tone pattern is required.

9. A method for providing the playback of an audio sequence within an electronic device, the electronic device including a memory element, a first processing unit and a second processing unit, the method comprising the steps of:
(a) storing data representing a tone pattern into the memory element;
(b) accessing the memory element with the first processing unit and obtaining the tone pattern data;
(c) providing the tone pattern data obtained by the first processing unit to the second processing unit; and
(d) the second processing unit providing a playback of tone pattern data.

10. The method of claim 9, wherein the tone pattern is downloadable to the first processing unit from an external source and further comprising the step of:
accessing the external source to obtain the tone pattern.

11. An apparatus that provides reduced processing requirements of a host processing unit for the playback of an audio sequence comprising:
a host processing unit coupled to a first memory element;
a supplemental processing unit coupled to a second memory element;
an interface means between the host processing unit and the supplemental processing unit;
the host processing unit being operative to:
store data representing a tone pattern into the first memory element;
detect an event that requires the playback of an audio sequence;
read at least a portion of the tone pattern data from the first memory element; and
provide the at least a portion of the tone pattern data to the supplemental processing unit through the interface means;
the supplemental processing unit being operative to:
receive the at least a portion of the tone pattern data; and
convert the at least a portion of the tone pattern data into an audio sequence.

12. The apparatus of claim 11, wherein the interface means is a shared memory element that the host processing unit and the supplemental processing unit can access.

13. The apparatus of claim 11, wherein the interface means is an electronic connection between the host processing unit and the supplemental processing unit.

14. The apparatus of claim 11, wherein the interface means is wireless interface.

15. An apparatus that provides reduced processing requirements of a host processing unit for the playback of an audio sequence comprising:
a host processing unit coupled to a first memory element;
a supplemental processing unit coupled to a second memory element;
an interface means between the host processing unit and the supplemental processing unit;
the host processing unit being operative to:
store data representing a tone pattern into the first memory element;
detect an event that requires the playback of an audio sequence;
read a first portion of the tone pattern data from the first memory element; and
provide the first portion of the tone pattern data to the supplemental processing unit through the interface means;
the supplemental processing unit being operative to:
receive the first a portion of the tone pattern data; and
convert the first portion of the tone pattern data into an audio sequence.

16. The apparatus of claim 15, wherein the interface means is a shared memory element, the shared memory element including two memory pages, a control register, and a status register, and the host processing unit is operative to provide the first portion of the tone pattern data to the supplemental processing unit by:
storing the first portion of the tone data into a selected page of the two memory pages; and
controlling the operation of the supplemental processing unit by setting and resetting bits in the control register.

17. The apparatus of claim 15, wherein the tone data is MIDI sequences.

18. The apparatus of claim 15, wherein the tone data is an MP3 file.

19. The apparatus of claim 15, wherein the tone data is a WAV file.

20. A method for a host processing unit to the playback of tone data by a supplemental processing unit, the tone data comprising note on events, note off events, stop sequence events and loop sequence events, the method comprising the steps of:
providing a first segment of tone to the supplemental processing unit;
setting a start status, the start status causing the supplemental processing unit to begin processing the tone data at the beginning;
setting a stop status, the stop status causing the supplemental processing unit to stop processing the tone data at the current location; and
setting a loop status, the loop status causing the supplemental processing unit, in response to processing a stop sequence event or a loop sequence event, to resume processing the tone data at the beginning.

21. An apparatus for enabling a host processing unit to control the operation of the playback of tone data by a supplemental processing unit, the tone data comprising note on events, note off events, stop sequence events and loop sequence events, the apparatus comprising:
a first memory page for receiving tone data from the supplemental processing unit;
a second memory page for receiving tone data from the supplemental processing unit;
a START_BIT, whereby when the START_BIT is in a first state, the supplemental processing unit will begin processing the tone data at the beginning of the first memory page;
a STOP_BIT, whereby when the START_BIT is in a first state, the supplemental processing unit will stop processing the tone data at the current location;
a LOOP_BIT, whereby when the LOOP_BIT is in a first state and the supplemental processing unit is processing a stop sequence event or a loop sequence event, the supplemental processing unit will resume processing the tone data at the beginning of the first memory page; and
a BOUNDARY_STATUS, whereby when the supplemental processing unit completes processing the tone data in a first memory page and begins processing the tone data in the second memory page, the BOUNDARY_STATUS is set to a first value and when the supplemental processing unit completes processing the one data in the second memory page and begins processing the tone data in the first memory page, the BOUNDARY_STATUS is set to a second value. 0557919.06
